(19) United States
(12) Patent Application Publication
(10) Pub. No.: US 2015/0262863 A1
(43) Pub. Date: Sep. 17, 2015

(54) MAGNETIC SCANNING SYSTEM FOR ION IMPLANTERS

(71) Applicant: GTAT Corporation, Merrimack, NH (US)

(72) Inventors: William H. Park, Somerville, MA (US); Geoffrey Ryding, Manchester, MA (US)

(21) Appl. No.: 14/657,325

(22) Filed: Mar. 13, 2015

Related U.S. Application Data
(60) Provisional application No. 61/952,610, filed on Mar. 13, 2014.

(51) Int. Cl. H01L 21/762; H01J 37/147; H01L 29/32; H01J 37/317

(52) U.S. Cl. CPC H01L 21/76254; H01J 37/3171; H01J 37/1475; H01L 29/32; H01J 2237/31701; H01J 2237/1526; H01J 2237/08

(57) ABSTRACT

A compact electromagnetic system is disclosed that is capable of scanning an ion beam in two orthogonal directions (e.g., for semiconductor doping or hydrogen induced exfoliation). In particular, according to embodiments of the compact electromagnetic system, the steel yoke, pole pieces, and excitation coils for both the X and Y axis have been integrated into a common structure.

### BACKGROUND OF THE INVENTION

1. Field of the Invention

The present invention relates to a magnetic scanning system for ion implanters.

2. Description of the Related Art

Ion implantation is a materials engineering process by which ions of a material are accelerated in an electrical field and impacted into a solid. This process is used to change the physical, chemical, or electrical properties of the solid. Ion implantation is often used in semiconductor device fabrication and in metal finishing, as well as various applications in materials science. Ion implantation equipment typically consists of an ion source, where ions of the desired element are produced, an accelerator, where the ions are electrostatically accelerated to a high energy, and a target chamber, where the ions impinge on a target, which is the material to be implanted. The energy of the ions, as well as the ion species and the composition of the target, determine the depth of penetration of the ions in the solid, i.e., the “range” of the ions.

There are various uses for ion implantation, such as the introduction of dopants (e.g., boron, phosphorus or arsenic) in a semiconductor. For instance, modification of semiconductors such as silicon wafers is often implemented by ion implanters, where a surface is uniformly irradiated by a beam of ions or molecules, of a specific species and prescribed energy. Another use for ion implantation is for cleaving (exfoliating) thin sheets (lamina) of hard crystalline materials such as silicon, sapphire, etc. Generally, this process involves implanting light ions into the material where they will stop below the surface in a layer. The material may then be heated (for example), causing the material above the implanted layer to cleave off or exfoliate in a sheet or lamina.

Usually, the physical size of the wafer or substrate (e.g., 8 inches or greater) is larger than the cross-section of the irradiating beam which deposits on the wafer as a spot of finite size (e.g., 1″). As such, in order to achieve a uniform implant (irradiance) during the ion implantation of a target substrate (e.g., wafer), it is customary to perform one or a combination of various techniques. For example, the wafer may be mechanically scanned through the beam (e.g., by reciprocal motion of the wafer and/or rotation about an axis), or the ion beam may be generated to uniformly cover one or both dimensions of the substrate.

A third technique is to scan the ion beam by varying either electrostatic or magnetic fields within the proximity of the ion beam. In a common variation, a time varying electric field (e.g., a magnetic deflection system) is used to scan the beam back and forth in one direction (e.g., X), while the wafer is moved in another, typically orthogonal, direction (e.g., Y), in order to scan the ion beam over a particularly selected “X-Y” region of the target substrate. In another variation, two magnetic deflection systems may be used in series to produce the desired X-Y scanning region. For example, as shown in FIG. 1, this is conventionally achieved by arranging for the ion beam to traverse two independent magnetic coil and pole structures (“scanners” 1 and 2), in order to correspondingly produce the desired X and Y scanning characteristics.

The use of two independent orthogonal scanner units, however, requires an insertion length within the beamline that accommodates the two serially arranged scanners. Also, due to the serial arrangement, the pole gap required in the second (downstream) scanner (scanner 2) is larger than the first (upstream) scanner (scanner 1), since the ion beam expands to a larger envelope dimension by virtue of the scanning action in the first unit and the drift distance between the two scanners. As such, the power required to produce the deflecting magnetic shields is greater in the second scanner than in the first.

### SUMMARY OF THE INVENTION

The present invention relates to a compact electromagnetic system capable of scanning an ion beam in two orthogonal directions, particularly for semiconductor doping or hydrogen induced exfoliation. In this invention, the steel yoke, pole pieces, and excitation coils for both the X and Y axis have been integrated into a common structure.

In particular, the combined X-Y scanner is more compact and requires a shorter insertion length in the beamline than conventional serially arranged scanners, and the power required to produce deflecting magnetic fields is reduced since the pole gaps are smaller for a given deflection angle (as opposed to the second scanner having to be larger). Furthermore, aberrations (non-linear deflection response, etc.) are reduced in the combined scanner unit that may otherwise occur in the serially arranged scanners.

In one embodiment, the scanner described herein may be used with proton induced exfoliation, which enables production of super thin layers of substrate, such as single crystal sapphire. These layers can then be bonded to less expensive materials so as to provide the properties of sapphire but at a lower overall cost. For instance, in this embodiments, a thick wafer of the substrate (e.g., sapphire) and irradiate it with a beam of high energy protons, such as hydrogen ions. These ions penetrate to a precise depth below the surface of the sapphire wafer, and they form a layer of small microbubbles of hydrogen gas. The wafer is then heated, and the surface layer separates, or exfoliates, to produce a thin layer with a precise thickness equal to the depth of the original implanted hydrogen. Now, because the layers are so thin, the process can be repeated many times so that multiple, high quality layers can be exfoliated from a single starting wafer. This proton induced exfoliation process uses a unique variation of the ion implantation process which is used routinely in the manufacture of silicon integrated circuits.

It is to be understood that both the foregoing general description and the following detailed description are exemplary and explanatory only and are intended to provide further explanation of the present invention, as claimed.

### BRIEF DESCRIPTION OF THE DRAWINGS

FIG. 1 shows an example prior art serially arranged scanner system.

FIG. 2, FIG. 3, and FIG. 4 show various embodiments of the compact electromagnetic system capable of scanning an ion beam in two orthogonal directions according to the present invention.

### DETAILED DESCRIPTION OF THE INVENTION

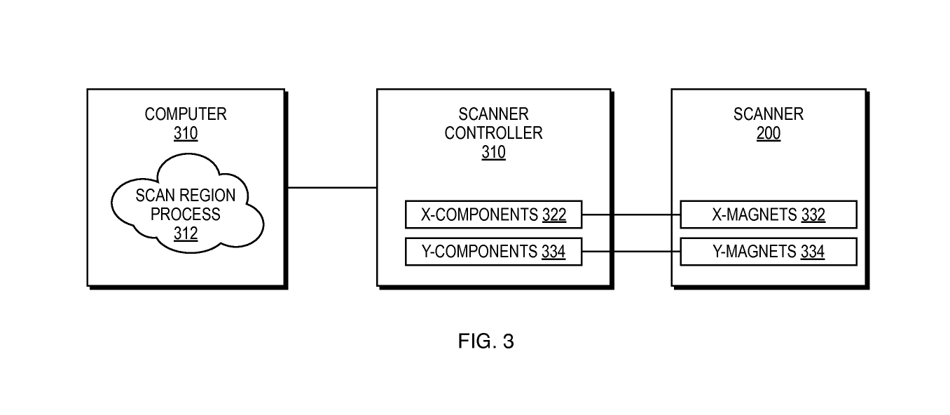

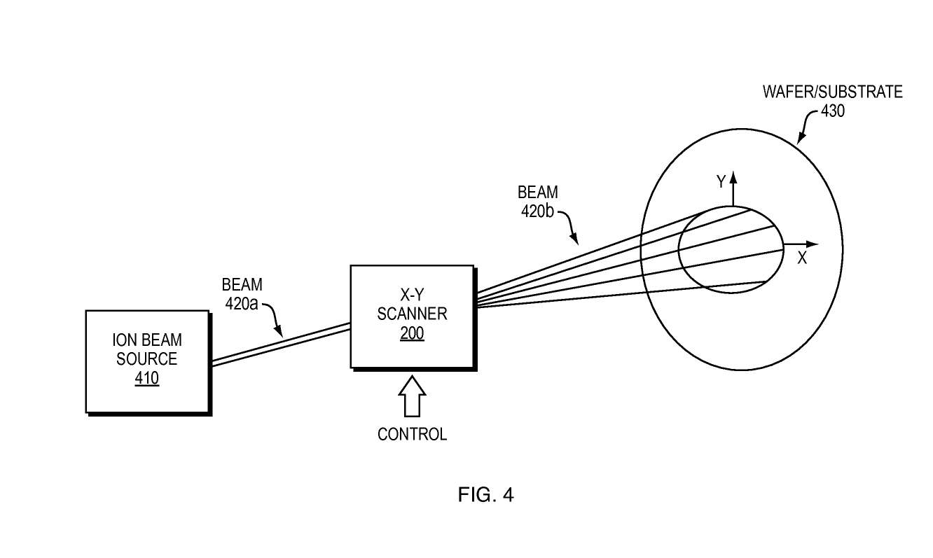

The present invention relates to a compact electromagnetic system capable of scanning an ion beam in two orthogonal directions. In particular, with reference to FIG. 2, an electromagnetic deflection system (“scanner”) 200 is configured to scan an ion beam over the target substrate in two orthogonal directions (e.g., “X” and “Y”). In particular, according to one or more embodiments herein, the electromagnetic deflection system consists of a singular structure incorporating components to deflect the ion beam electromagnetically in each of the two orthogonal directions.

As shown in FIG. 3, the scanner 200 operates according to computer instructions from a computer 310 (and associated “scan region process 312), which feeds controlling instructions to a scanner controller 320. The controller 320 receives the instructions, and converts them into electrical signals to control the scanner 200. In particular, separate electrical components (“X-component” 322 and “Y-component” 324), such as the electrical circuitry configured to create electronic flow through an electromagnetic system, are configured to interface with corresponding electromagnetic hardware (X and Y magnets 332 and 334, respectively) of the scanner 200. Note that the computer 310, controller 320, and scanner 200 may be co-located in any combination (e.g., controller 320 and scanner 200), or may be individual (separate) devices interconnected by communication links. For instance, an ion beam controller 320 need not be a separate controller device, but may be a wholly contained apparatus configured to generate the beam, and control the scanner 200 to produce the desired result. Accordingly, their visual separation in the Figures as well as their separate description is not meant to limit the scope of the invention described herein.

With reference to FIG. 4, an ion beam source (generator) 410 is configured to generate an ion beam 420a toward a target substrate 430. By passing through via scanner 200, an ion beam controller (320 in FIG. 3) may then control the ion beam generation and/or scanning to implant ions into the target substrate across a particular X-Y range (e.g., and at a particular depth). Note that scanner 200 may be spaced at a drift length (distance) away from the target substrate 430 to account for a desired size (X-Y coverage) of the beam at the target substrate, for example, for singular wafers or small batches of wafers (closer for less coverage), or for larger production tool batches (further away for more coverage). As may be appreciated by those skilled in the art, the target substrate 430 may comprise silicon, sapphire, or any other crystalline structure for which ions may be implanted using an ion implanter.

With general collective reference to FIGS. 2-4, the techniques herein provide an ion beam magnetic scanning system that creates magnetic deflections of ions in orthogonal directions (e.g., X and Y) using a singular structure. In this manner, ions travelling along beam path 420a more or less along the z-axis are caused to undergo deflections (e.g., oscillatory) in the xy-plane. At an instant in time, ions that have just emerged from the scanner 200 remain in the form of a beam, but now the X-Y direction of the beam 420b is deflected at an angle to the z-axis as a result of the X and Y magnetic deflection produced in the scanner 200. FIG. 4 in particular shows a typical transformation of the envelope of the ions within the beam 420b as the beam passes from the scanner 200 to the substrate 430. Note that in one or more embodiments herein, transport of the beam may occur in a high vacuum. Note also that though the X-Y scanner is configured to deflect the ion beam 420b in both the X and Y directions simultaneously, singular directional deflection in a first direction (e.g., X) may also be achieved by simply not deflecting the beam in a particular orthogonal direction (e.g., Y).

With reference again to FIG. 2, the singular structure scanner 200 herein comprises a singular steel yoke for both of the two orthogonal directions, and pole pieces and excitation coils for each of the two orthogonal directions. Generally, the components for each of the two orthogonal directions may be substantially magnetically identical, but there are instances where one direction's components may be differently configured. For example, though the identical structures of the X and Y directions create a generally square shape for the scanner 200, rectangular shapes may be used, such as where one dimension requires greater beam deflection than another (e.g., depending upon an intended use of the ion beam scanning system). Also, in one embodiment, the magnetic components 332 and 334 may comprise laminated magnets, and they may also be configured to prevent magnetic columnating, as may be appreciated by those skilled in the art.

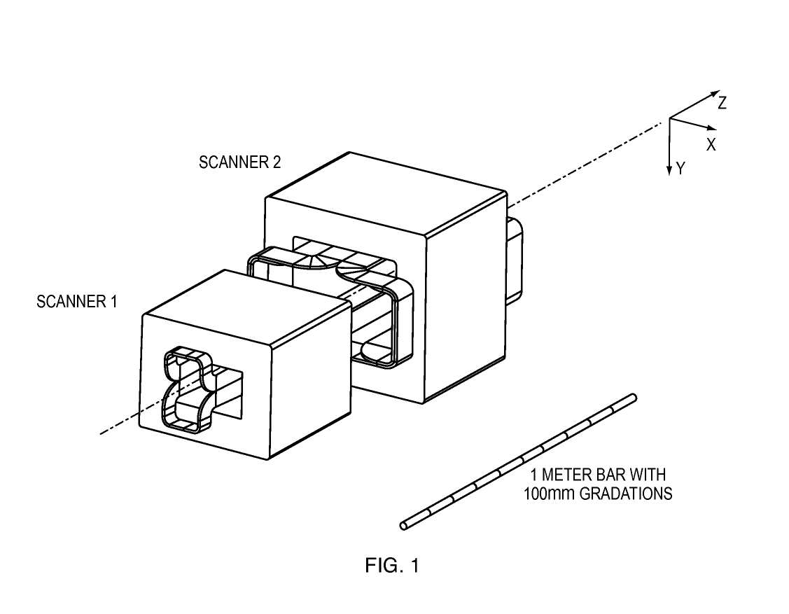

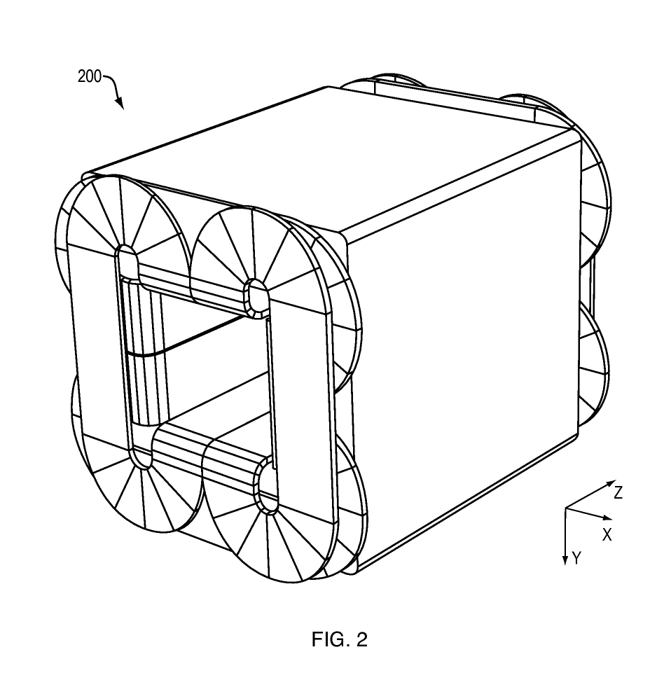

Advantageously, by scanning the beam in both horizontal and vertical directions, the ions (protons) are very evenly distributed below the surface of the substrate with a uniformity variation of less than 1%. The combined magnetic X-Y scanner is more compact than prior art systems (such as that shown in FIG. 1), and requires a shorter insertion length in the beamline, as there is only a single X-Y scanner, and not separate X and Y scanners. In addition, the power required to produce deflecting magnetic fields is reduced since the pole gaps are smaller for a given deflection angle, as opposed to having a second scanner that is larger than the first. In particular, in prior systems, after passing through a first scanner, the beam is expanded significantly in one corresponding direction (e.g., the X dimension), and as such, the orthogonal second scanner (e.g., the Y dimension) must be larger to account for this initial beam spread. Furthermore, aberrations (non-linear deflection response, etc.) may occur due to the nature of serially arranged scanners are similarly reduced in the combined scanner unit. Still further, since both axes may be magnetically identical, this allows similar scan frequencies on both axes if desired, as opposed to the typical “fast axis/slow axis” configuration of serially arranged scanners, as may be appreciated by those skilled in the art.

Note that in one embodiment, ion implantation may occur during a layer exfoliation process to exfoliate a layer of the target substrate. For instance, an illustrative layer exfoliation process may comprise providing a donor body of the target substrate, implanting through a top surface of the donor body with an ion dosage. Using this implantation method, a cleave plane is formed beneath the top surface of the donor body, and a thin layer can then be exfoliated from the donor body along this cleave plane. The ion dosage can comprise, for example, hydrogen, helium, or a combination thereof. Implantation conditions can be varied as needed to produce a particular lamina (e.g., sapphire lamina) having targeted properties, such as thickness and strength. For example, the ion dosage may be any dosage between about 1.0×10¹⁴ and 1.0×10¹⁸ H/cm², such as 0.5-3.0×10¹⁷ H/cm². The dosage energy can also be varied, such as between about 500 keV to about 3 MeV. In some embodiments, the ion implantation temperature may be maintained between about 200 and 950° C., such as between 300 and 800° C. or between 550 and 750° C. In some embodiments, the implant temperature may be adjusted depending upon the specific type of material and the orientation of the sapphire donor body. Other implantation conditions that may be adjusted may include initial process parameters such as implant dose and the ratio of implanted ions (such as H/He ion ratio). In other embodiments, implant conditions may be optimized in combination with exfoliation conditions such as exfoliation temperature, exfoliation susceptor vacuum level, heating rate and/or exfoliation pressure. For example, exfoliation temperature may vary between about 400° C. to about 1200° C. By adjusting implantation and exfoliation conditions, the area of the resulting lamina that is substantially free of physical defects can be maximized. The resulting sapphire layer may be further processed if needed, such as to produce smooth final surfaces.

In one specific embodiment, the scanner system described herein may use a much higher voltage than conventional techniques to accelerate the ions (e.g., hydrogen) to high enough velocity so that they penetrate to the required depth below the surface of the substrate (e.g., sapphire). For instance, it is capable of producing hydrogen ion beams at energies up to 2 MeV, and with a high intensity (e.g., currents up to 50 mA). These high currents are required to meet the productivity and cost objectives of large scale manufacturing of sapphire lamina. In addition to the vacuum environment before, the scanner system (e.g., an accelerator) may be packaged in a high-pressure tank, using pressurized gas that has very good electrical insulation properties, enabling operation at these high voltages. Also, in one specific embodiment, after emerging from an accelerator (beam generator), the beam is focused and deflected through 45 degrees by an analyzing magnet which filters out all unwanted ions. In so doing, the beam transported to the process chamber is greater than 99.9% pure.

Note that the present invention may be used to prepare a cover plate of an electronic device. In particular, the method comprises the steps of providing a donor body of sapphire, implanting through the top surface of the donor body with an ion dosage to form a cleave plane beneath the top surface, exfoliating the sapphire layer from the donor body along the cleave plane, and forming the cover plate comprising this sapphire layer, which has a thickness of less than 50 microns. Preferably, the ion dosage comprises hydrogen or helium ions.

For example, there are many types of mobile electronic devices currently available which include a display window assembly that is at least partially transparent. These include, for example, handheld electronic devices such media players, mobile telephones (cell phones), personal data assistants (PDAs), pagers, and laptop computers and notebooks. The display screen assembly may include multiple component layers, such as, for example, a visual display layer such as a liquid crystal display (LCD), a touch sensitive layer for user input, and at least one outer cover layer used to protect the visual display. Each of these layers are typically laminated or bonded together.

Many of the mobile electronic devices used today are subjected to excessive mechanical and/or chemical damage, particularly from careless handling and/or dropping, from contact of the screen with items such as keys in a user's pocket or purse, or from frequent touch screen usage. For example, the touch screen surface and interfaces of smartphones and PDAs can become damaged by abrasions that scratch and pit the physical user interface, and these imperfections can act as stress concentration sites making the screen and/or underlying components more susceptible to fracture in the event of mechanical or other shock. Additionally, oil from the use's skin or other debris can coat the surface and may further facilitate the degradation of the device. Such abrasion and chemical action can cause a reduction in the visual clarity of the underlying electronic display components, thus potentially impeding the use and enjoyment of the device and limiting its lifetime.

Various methods and materials have been used in order to increase the durability of the display windows of mobile electronic devices. For example, polymeric coatings or layers can be applied to the touch screen surface in order to provide a barrier against degradation. However, such layers can interfere with the visual clarity of the underlying electronic display as well as interfere with the touch screen sensitivity. Furthermore, as the coating materials are often also soft, they can themselves become easily damaged, requiring periodic replacement or limiting the lifetime of the device.

Another common approach is to use more highly chemically and scratch resistant materials as the outer surface of the display window. For example, touch sensitive screens of some mobile devices may include a layer of chemically-strengthened alkali aluminosilicate glass, with potassium ions replacing sodium ions for enhanced hardness, such as the material referred to as “gorilla glass” available from Corning. However, even this type of glass can be scratched by many harder materials, and, further, as a glass, is prone to brittle failure or shattering. Sapphire has also been suggested and used as a material for either the outer layer of the display assembly or as a separate protective sheet to be applied over the display window. However, sapphire is relatively expensive, particularly at the currently available thicknesses, and is not readily available as an ultrathin layer.

Accordingly, use of the compact magnetic scanner herein may provide the ion implantation that can be used for the exfoliation of one or more sapphire layers having a thickness of less than 50 microns, such as less than 30 microns, less than 25 microns, and less than 15 microns.

The foregoing description of preferred embodiments of the present invention has been presented for the purposes of illustration and description. It is not intended to be exhaustive or to limit the invention to the precise form disclosed. Modifications and variations are possible in light of the above teachings, or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A system for implanting ions into a target substrate, the system comprising:
an ion beam generator configured to generate an ion beam toward a target substrate;
an electromagnetic deflection system configured to scan the ion beam over the target substrate in two orthogonal directions, the electromagnetic deflection system consisting of a singular structure incorporating components to deflect the ion beam electromagnetically in each of the two orthogonal directions; and
an ion beam controller configured to control the ion beam generation and scanning to implant ions into the target substrate.

2. The system as in claim 1, wherein the singular structure comprises a singular steel yoke for both of the two orthogonal directions and pole pieces and excitation coils for each of the two orthogonal directions.

3-4. (canceled)

5. The system as in claim 1, wherein the components for each of the two orthogonal directions are substantially magnetically identical.

6. The system as in claim 1, wherein the singular structure is spaced at a drift length away from the target substrate to account for a desired size of the beam at the target substrate.

7. The system as in claim 1, wherein the components comprise laminated magnets.

8. The system as in claim 1, wherein the components are configured to prevent magnetic columnating.

9-10. (canceled)

11. A method for implanting ions into a target substrate, the method comprising:
providing a target substrate;
generating an ion beam toward the target substrate;
scanning the ion beam over the target substrate by passing the beam through an electromagnetic deflection system configured to scan the ion beam in two orthogonal directions, the electromagnetic deflection system consisting of a singular structure incorporating components to deflect the ion beam electromagnetically in each of the two orthogonal directions; and
controlling the ion beam generation and scanning to implant ions into the target substrate.

12. The method as in claim 11, wherein the singular structure comprises a singular steel yoke for both of the two orthogonal directions and pole pieces and excitation coils for each of the two orthogonal directions.

13-14. (canceled)

15. The method as in claim 11, wherein controlling the ion beam comprises implanting ions during a layer exfoliation process to exfoliate a layer of the target substrate.

16. The method as in claim 15, wherein the layer exfoliation process comprises:
i) providing a donor body of the target substrate comprising a top surface;
ii) implanting through the top surface of the donor body with an ion dosage to form a cleave plane beneath the top surface; and
iii) exfoliating the layer from the donor body along the cleave plane.

17. The method as in claim 11, wherein the components for each of the two orthogonal directions are substantially magnetically identical.

18. The method as in claim 11, further comprising:
spacing the singular structure at a drift length away from the target substrate to account for a desired size of the beam at the target substrate.

19. The method as in claim 11, wherein the components comprise laminated magnets.

20. The method as in claim 11, wherein the components are configured to prevent magnetic columnating.

21-22. (canceled)

23. An ion-implanted target substrate, comprising:
a target substrate; and
implanted ions, the ions implanted by an ion beam generated toward the target substrate and scanned over the target substrate by passing the beam through an electromagnetic deflection system configured to scan the ion beam in two orthogonal directions, the electromagnetic deflection system consisting of a singular structure incorporating components to deflect the ion beam electromagnetically in each of the two orthogonal directions.

24. The ion-implanted target substrate as in claim 23, wherein the target substrate is silicon.

25. The ion-implanted target substrate as in claim 23, wherein the target substrate is sapphire.

26. The ion-implanted target substrate as in claim 23, wherein the ions comprise hydrogen ions.

27. The ion-implanted target substrate as in claim 23, wherein the ions comprise helium ions.
